(19) United States
(12) Patent Application Publication
(10) Pub. No.: US 2002/0173864 A1
(43) Pub. Date: Nov. 21, 2002

(54) Automatic volume control for voice over internet

(75) Inventor: Shawn W. Smith, Ventura, CA (US)

Correspondence Address: KOPPEL & JACOBS, Suite 107, 555 St. Charles Drive, Thousand Oaks, CA, 91360, US

(73) Assignee: CRYSTAL VOICE COMMUNICATIONS, INC

(21) Appl. No.: 09/860,929

(22) Filed: May 17, 2001

(51) Int. Cl. G06F 17/00; H03G 3/00

(52) U.S. Cl. 700/94; 381/104; 381/105; 381/107

(57) ABSTRACT

The invention includes a method and system for digitally and automatically adjusting the audio volume of digitized speech signals received over a network such as the internet. The method includes: estimating an average frame volume estimate (VE) for each frame of data; calculating from a plurality of successive frame volume estimates at least one moving average of the volume estimates; comparing at least one of the moving averages with a known desired level that is associated with a psychoacoustically desirable audio volume level; calculating, independently of any compression applied to the data frame during encoding, a digital gain factor based upon the results of the aforementioned comparison; and adjusting a volume level of the audio data based upon the digital gain factor. The system of the invention includes several modules, which could be executed by software run on a microprocessor, for carrying out the method of the invention.

### BACKGROUND OF THE INVENTION

1. Field of the Invention

This invention relates to digital voice communications in general and more specifically to digital voice communication over a non-ideal packet network, such as providing long distance telephone service over the Internet using Voice-over-Internet-Protocol (VOIP).

2. Description of the Related Art

Voice Over Internet Protocol (VOIP) techniques can be used to transport digitized audio signals (phone calls) from one location to another over a data network. They can also be used to carry the sound of a voice between personal computers (PCs) in a point-to-point or broadcast protocol. Many other variations of the origin and destination of a VOIP call exist, including cases where there is just one user who listens to pre-recorded computer information such as Voice Mail or stock quotes. In all these cases, the listener would prefer that a normal pleasant volume level be maintained so that no matter the source of the audio it sounds “just right” to the listener.

A traditional telephone and computer solution to the problem of keeping constant listening levels is to apply Automatic Gain Control or other compression at the origin of the input audio, typically just prior to digitization and transmission through the network. This solution performs adequately on a uniformly designed and controlled network such as the traditional PSTN where calls are carried on just one set of lines from one well known location to another with well understood end-to-end amplitude loss and a detailed specification of the end device amplitude requirements.

Today's eclectic world of communications has complicated the traditional PSTN design. The origin of the sound is not necessarily a well-controlled telephone handset—instead it might be a PC microphone, a cell phone, an automated response system, or other device which may not conform to the typical “telephone” volume levels. Adding to the problem of volume variation from the input device, we now often transmit the speech through many tandem networks: for example, a cell phone calls long distance to an office, where the call is forwarded to a call center, and subsequently converted into VOIP where it travels across the country, only to be converted into yet another cell phone call to reach the intended user (on travel). There will be changes in gain—most often losses—as the call passes through these many network translations. Finally the end device, just like the sending one, may not be a standard telephone. Instead it might be a set of Stereo Speakers on a PC, or the output of a wireless PDA. The input requirements and efficiencies of these speakers may not match those of a typical analog, wired connection telephone.

Thus, it is increasingly difficult to know what path a call will take, how much loss it will encounter, and what the signal levels are required by the listening device. This is especially true for VOIP systems, since the receiving system typically has no knowledge the device which originated the call, nor what path it took on the way to the receiver. The signal might have had lots of attenuation through many networks, or might be direct and almost loss free. As VOIP systems begin to inter-operate, calls from unknown devices will have to be accepted, and different vendors may have made different assumptions about just how loud the VOIP audio data should be when encoded. Not all vendors will provide identical gain control or compression on the sending (encoding) side.

### SUMMARY OF THE INVENTION

In view of the above problems, the present invention is a method and system for digitally and automatically adjusting the audio volume of digitized speech signals received over a network such as the internet. The signal is represented by multiple digital bytes of encoded audio data organized into frames and transmitted serially through the network, then received at a digital receiving device (such as a personal computer), where the audio is reproduced for a listener.

The method of the invention includes: estimating an average frame volume estimate (VE) for each frame of data; calculating from a plurality of successive frame volume estimates at least one moving average of the volume estimates; comparing at least one of the moving averages with a known desired level that is associated with a psychoacoustically desirable audio volume level; calculating, independently of any compression applied to the data frame during encoding, a digital gain factor based upon the results of the aforementioned comparison; and adjusting a volume level of the audio data based upon the digital gain factor.

Preferably, at least two moving averages are calculated: a fast moving average and a slow moving average. Gain is adjusted in response to the fast moving average for attacking signals (increasing in volume) and in response to the slow moving average for decaying signals (decreasing in volume).

The invention also includes a system for digitally and automatically adjusting the audio volume of a digitized speech signal reproduced by a digital receiving device, the signal represented by multiple digital bytes of encoded audio data organized into frames, transmitted through a distributed network and received at the digital receiving device for reproduction. The system includes several modules: a first module estimates audio volume of each frame of data to produce for each said frame a corresponding volume estimate. A second module calculates from a plurality of successive volume estimates at least one moving average of the volume estimates. A third module compares the at least one moving average with a predetermined desired level that corresponds to a psychoacoustically desirable audio volume. A fourth module calculates, independently of any compression applied to the digital frame of data during encoding, a digital gain factor based upon the comparison performed by said third module. A fifth module rescales the audio data based upon the digital gain factor. The rescaled audio data is such that it will, after conversion to analog signal and ultimately to sound, produce an acceptable volume for a listener.

Preferably the system is responsive to a fast moving average for attacking audio signals and a slow moving average for decaying audio signals.

These and other features and advantages of the invention will be apparent to those skilled in the art from the following detailed description of preferred embodiments, taken together with the accompanying drawings, in which:

### BRIEF DESCRIPTION OF THE DRAWINGS

FIG. 1 is a block diagram showing the system of the invention in the context of a typical voice over internet communication link;

FIG. 2 is a high level block diagram showing more detail of the automatic volume control in accordance with the invention; and

FIG. 3 is a flow diagram of a method of automatic volume control in accordance with the invention; and

FIG. 4 is a flow diagram of a method of adjusting gain factor dynamically toward a nominal center over time periods when no new speech data is received, which method enhances performance of the invention.

### DETAILED DESCRIPTION OF THE INVENTION

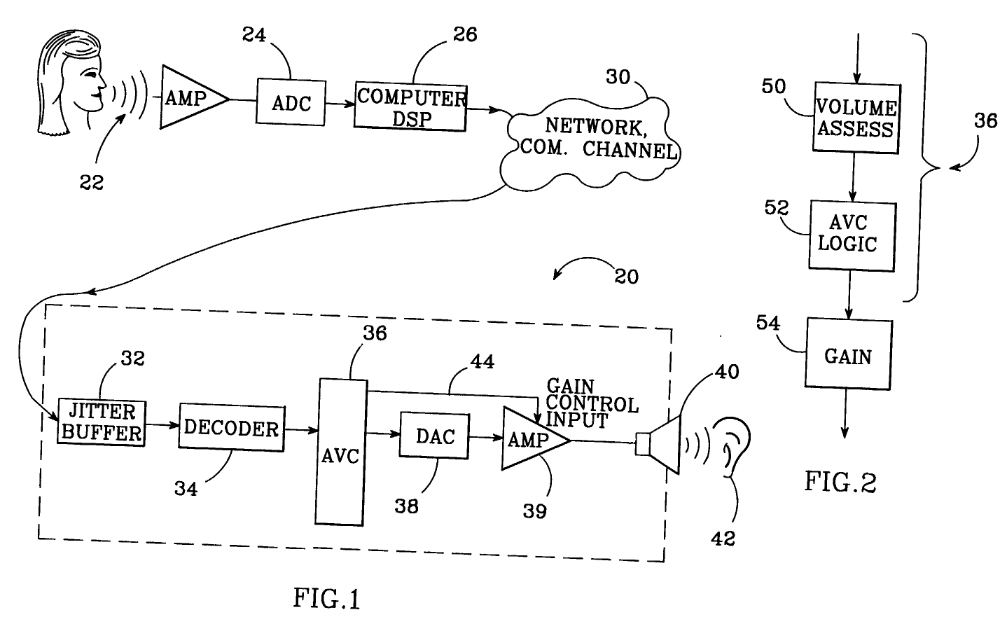

A system in accordance with the invention is shown in block form generally at 20 in FIG. 1 in the context of a typical VOIP communication system. An audio source (typically a human voice 22) is converted typically to an analog electronic signal which is in turn digitized by an analog to digital converter (ADC) 24. The resulting digital signal is processed by a computer and/or digital signal processor 26 and is typically encoded and/or compressed by said processor 26 (typically a general purpose microprocessor). The digital signal is then packetized and transmitted through a signal channel 30.

The signal channel 30 is treated here very generally as a “black box.” This channel is considered for purposes of this description to include any or all layers of communication processing, including the modems, physical layer, network routing, all other layers including but not limited to those commonly identified in thr Transmission Control Protocol/Internet Protocol (TCP/IP) or the Open Systems Interconnection (OSI) 7 layer model.

After transmission the digital signal is received by the receiving apparatus 20 (reception should be understood in this context to include recognition by a modem or other receiving apparatus and appropriate grouping into digital words and bytes). Some or all of the modules of the receiving apparatus 20 could be executed by either a general purpose microprocessor system or a dedicated digital signal processor. The incoming data is typically stored in a “jitter buffer” 32, then decoded including decompression) by a decoder 34. A novel automatic Volume Control (AVC) module 36 then further expands or compresses the digital audio signal, independently of any compression or decompression which was applied in the coder and decoder 34. The digital signal is then converted into analog form by a digital to analog converter (DAC) 38 and amplified by an amplifier 39. The Analog waveform is transduced into audible sound by a speaker or headset 40 for a listener 42.

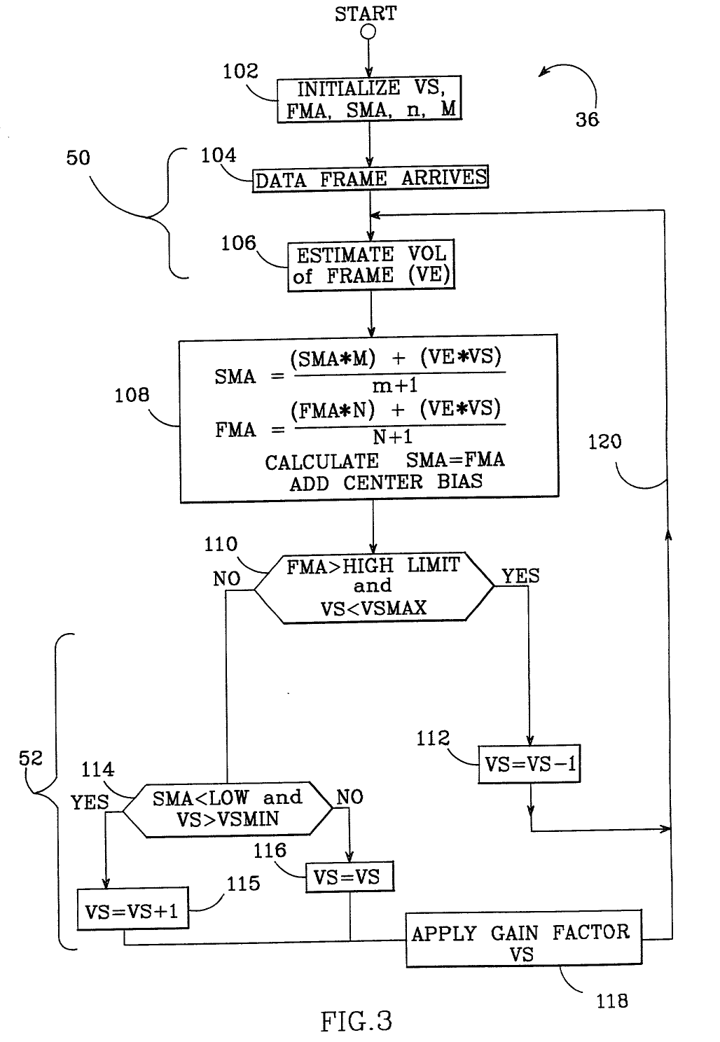

Optionally, amplifier 39 is a variable gain amplifier responsive to a gain control input 44. In some embodiments, the AVC module 36 provides a gain control input 44 to the amplifier 39, causing the amplifier to vary the gain in response to a gain control factor (as more fully described below in connection with FIG. 3).

Typically, but not necessarily, a full duplex communication channel is used, so that the listener 42 provides the human voice 22 for a reciprocal channel of communication (not shown).

Further details of the AVC module 36 are shown in FIG. 2. Three major modules (or procedural steps) are included: a Volume assessment module 50 assesses the volume of each of multiple frames of audio data; AVC logic 52 calculates moving averages and peak loudness indices based on multiple data frames and determines the most appropriate volume control parameters to produce psychoacoustically acceptable volume levels; finally, gain module 54 adjusts the volume of the digital audio data (typically by multiplication by a gain factor) in accordance with the volume control parameters determined by AVC logic module 52.

It is to be understood that the volume control of the invention is in addition to and independent of any other expansion which might be employed to complement encode-side compression or automatic gain control at the transmitter.

FIG. 3 shows a more detailed flow chart of the automatic volume control in a particular software embodiment of the invention, suitable for execution from random access memory by any general purpose microprocessor. In step 102, parameters Volumesetting (VS), Fastmoving Average (FMA), SlowMoving Average (SMA), N, and M (integer counters) are all initialized. Suitably, VS is set to 0; FMA is set to 16 increments, which corresponds to a target or nominally “normal” volume level on a 32 decibel log scale, with 2 db per increment; SMA is set to 16 on the same scale; N is suitably set to 16; and M to 128.

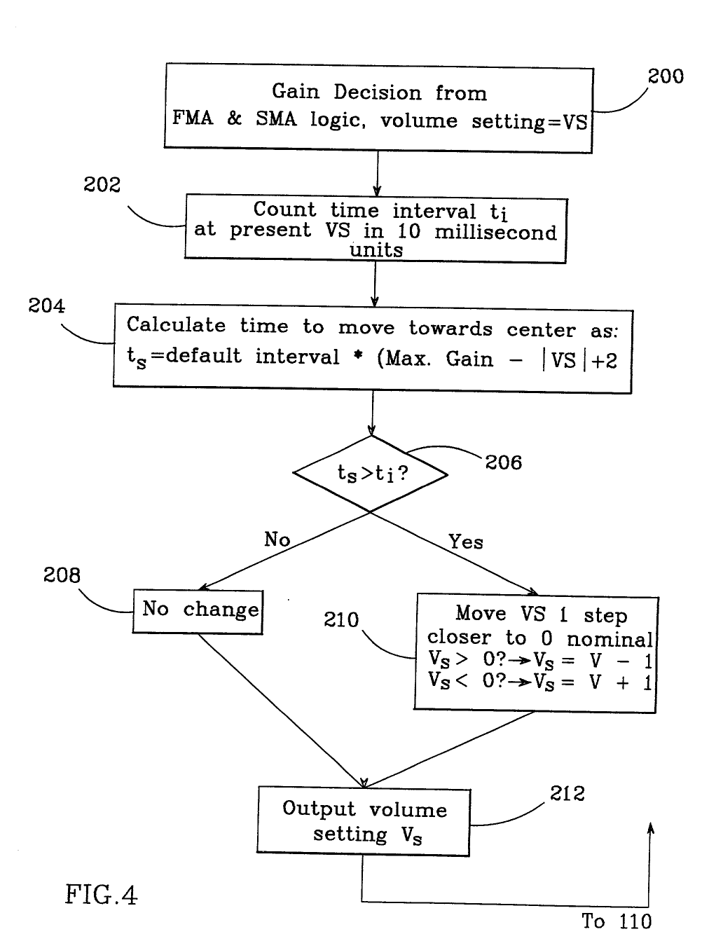

In step 104, a frame of data arrives (typically in compressed or encoded form) from a network such as the internet. A volume estimate is computed from the compressed frame of data in step 106 (corresponding to module 50 in FIG. 2). Typically, the volume estimate can suitably be made by computing a root-mean-square (RMS) or mean-square value of sets of successive audio samples. A more accurate estimate can be made by computing the RMS value of the decoded audio data, but it has been found that in most cases the estimate of the encoded audio packet is sufficiently accurate to produce acceptable volume control with the invention, and this alternative is more computationally simple. For example, the volume estimate could suitably be made from logarithmically compressed digitized audio data without first exponentially expanding the digitized audio. This method is adequate and considerably relaxes the need for extensive real time calculation. More detail on specific volume estimation methods is given below, following the discussion of FIG. 4.

It is preferred that bytes corresponding to silence be excluded from the calculation the volume estimate. Human speech includes many such silences, which would otherwise unduly affect the volume estimate in a manner which interferes with the volume control of the invention. In some methods of encoding or compressing the speech data, such silences are eliminated or extremely compressed during encoding. However, to allow general compatibility of the invention with multiple compression methods, it is most preferred that incoming audio data be compared to a minimum threshold, and that levels below the threshold be excluded from the calculation of the volume estimate in step 106 (module 50 in FIG. 2). A minimum threshold of 18 decibels below nominal “normal” volume has been found suitable.

A volume estimate parameter is preferably represented by a fixed point number, for example a positive integer between 0 and 32 which approximates the volume estimate in decibels. The decibel scale requires conversion in the volume estimate module, but is more convenient than a linear volume estimate in subsequent calculations.

Based upon the volume estimate (VE) from a current frame, parameters are computed (or updated in subsequent iterations) in step 108. FMA and SMA are computed as a moving average, suitably by the equations shown within step 108. In addition, a center bias is preferably added as discussed below in connection with FIG. 4.

In accordance with the equations given in step 108, the Fastmoving average is averaged over N frames, while the Slowmoving average is averaged over M frames. The previous selection of N=16 and M=128 is typical but these values are not limiting. In a typical application, the incoming audio data is organized into frames of 20 milliseconds in duration, each including 20 bytes of data (typically 8 bits/byte). For this data structure the values of N and M suggested above produce psychoacoustically acceptable results.

Next, a pair of decisions is made. The first decision 110 computes logically whether FMA is larger than a user defined high limit (highlimit), and VS is smaller than a user defined maximum VS (VSmax). If this logical proposition is true, the audio is displaying an “attack”; In such case the flow leads to step 112 and VS is decremented (gain is decreased). If the proposition in decision box 110 is false, a further test 114 is computed. If the SMA is less than a user defined Low limit (lowlimit) and VS is greater than a user defined minimum, then the audio is exhibiting “decay”; In this case VS is incremented (gain is increased, step 115). If neither attack or decay is occurring, the gain parameter VS is unchanged (step 116 ).

The parameters highlimit and lowlimit are chosen as predetermined levels which are found to define a psychoacoustically desirable audio volume range. Preferably, a method is provided for the user to input and adjust these parameters before use, based upon test audio levels.

After the parameters FMA, SMA, VS are updated based on the current data packet, the updated gain parameter VS controls a gain factor applied to the audio data (step 118, during or after decompression). Gain application is typically by simple multiplication by a fixed point VS. For example, multiplication by a factor of two (or left shift one place in a binary byte) yields a gain increase of 6 decibels (fourfold increase in power). Alternatively, other known methods could be applied. Floating point multiplication could be used, particularly if a floating point co-processor is included in the receiving apparatus 20.

In one alternate embodiment of the invention, a variable gain, analog amplifier 39 is used to provide the gain control by multiplying the output by a gain factor, where the gain factor is determined by the method of steps 102 through 116 described above. The volume control module 36 produces an output in response to the calculated gain control factor. This output provides a gain control input to the analog, variable gain amplifier (39, shown in FIG. 1). The amplifier varies its gain to adjust the analog signal level (volume) in accordance with the gain factor. This alternate embodiment is appropriate in a system environment in which a variable gain analog amplifier is available and convenient; in systems without such a device, level control by digital rescaling is more appropriate.

With most common methods of encoding audio, a multiplying factor is applied during decompression independent of any gain control. In such cases the decompression factor can simply be adjusted to account for the VS. Additional multiplications are thus reduced or eliminated.

After step 118, the method returns via return path 120 to step 104 and repeats, reiteratively, to process further packets of audio data as they arrive.

Several features of the invention particularly distinguish the method of the invention from prior methods. For example (and not by way of limitation), the method of the invention applies digital volume control to received digitized audio packets independent of any compression which was applied during encoding or compression of the packets. At least two gain control time constants are preferably applied (which depend upon variables M and N as discussed above. Gain is adjusted according to different time constants for attacking and decaying waveforms. In particular, attacking waveforms are tested by a fast moving average (short time constant) and produce gain adjustments which respond relatively faster that the adjustments in response to decaying waveforms. Decaying waveforms are tested against a relatively slower moving average, as it has been found that the human ear is relatively more tolerant of sudden but temporary decreases in volume (but intolerant of sudden increases, which can cause “clipping” in analog output circuits and devices). The terms “fast” and “slow” are, of course, relative; both the attacking and decaying time constants in the invention are typically longer than most conventional automatic gain control. The volume control of the invention has been found most effective if tuned to a relatively small dynamic range, for example with gain between −12 db and +12 db.

Preferably, a “center bias” adjustment is performed in step 108. Details of one exemplary center bias adjustment method are shown in FIG. 4. In this particular method, a decay feature modifies certain gain settings dynamically over time. If the gain setting is either very high or low (extreme), and there is a lack of speech data over an extended period of time, then the gain factor is modified so that it decays toward a center (nominal unity gain factor, or zero decibels gain) over time.

Specific operation of the exemplary center bias decay adjustment module are as follows. First gain decision from the FMA, SMA and VS calculations are retrieved (step 200). Next, the module counts (step 202) the real time interval Ti during which the VS has been stable (essentially unchanging). This interval is suitably counted in 10 millisecond units. The module next calculates (step 204) the time ts at which the gain should begin to decay toward center, according to the equation shown. The default interval is suitably set to 1.2 seconds and the maxgain allowed is suitably 12 decibels. (maxgain, VS and the constant 2 in step 204 are given in decibels.)

A decision is then made (step 206): if ts is greater than ti, it is too soon to adjust toward center and no change is made to VS (step 208); on the other hand, if ts is greater than ti the VS is adjusted (step 210) one increment toward center (unity gain). Suitably, increments of 2 db are used. The result of the equations given is that large gain settings are adjusted toward center more quickly than small settings. For example, with default interval of 1.2 seconds and maxgainallowed of 12 db, a setting of 4.0 db would be reduced to 2.0 db after (1.2*(12−4+2))=12 seconds. The remaining setting of 2.0 would then be further reduced to unity gain after (1.2*(12−2+2))=14.4 seconds. Thus, very extreme gain settings decay quickly (in the absence of new speech data) but the reduction slows as the gain setting approaches a nominal unity gain setting.

The adjusted volume setting VS is then output and applied as previously discussed in connection with FIG. 3.

The center bias feature adds robustness to the volume control method and allows it to adapt more quickly to changes in the input signal. Spikes, glitches and other noises are thus prevented from falsely altering the gain setting to an inappropriate level.

The volume estimation module (step 106 of FIG. 3) in some embodiments takes advantage of certain characteristics of some encoding schemes to greatly simplify and speed up the calculation of an estimate. It is possible with many types of know incoding to extract a gain estimate of each frame without performing full decompression. For example, in some compression schemes a field (one or more defined bytes) within the transmitted data frame is defined for filter gain. In such a frame, the filter gain field can be converted into decibels and used as a rough estimate of the volume of the entire frame, without decompressing the frame. More specifically, the Audiocodes NetCoder 8.0 compression method defines a 20 byte frame, with a master gain factor sored as a 5 bit field in bit positions 31 through 35. In an embodiment intended to function with this compression method, the invention would convert the 5 bit gain field to decibels and use this raw figure as the volume estimate for the frame. The Audiocodes NetCoder 8.0 specification is available from AudioCodes, Inc., 2841 Junction Ave. Suite 114, San Jose, Calif. 95134 or on the internet at www.audiocodes.com.

Other compression standards such as G729 can also be advantageously parsed to extract volume estimates without full decompression. (specification available from ITU Place des Nations, CH-1211 Geneva 20, Switzerland or:

http://www.itu.int/itudoc/itu-t/rec/g/g700-799/index.html)

In this compression standard gain index is also stored in a specified field. The gain index can be extracted, decoded, and converted into decibel form then used as a volume estimate in the present invention. Generally speaking, in one embodiment of the invention the volume estimate is derived by decoding a gain index from a pre-defined data field in an encoded data frame, where the pre-defined data field is smaller than the complete frame. In such embodiments the gain control of the invention is in addition to but not completely independent of any gain control encoded into the frame. However, the additional gain control of the invention follows different logic and time constants which augment any gain control which was a part of the encoding scheme.

Appendix 1 is a software listing giving source code in the C++ language for one specific embodiment of a volume control method in accordance with the invention. The particular embodiment given is succinct and relatively efficient, therefore suitable for execution on a general purpose microprocessor with many popular voice over internet programs.

While several illustrative embodiments of the invention have been shown and described, numerous variations and alternate embodiments will occur to those skilled in the art. For example, the invention has been described in the context of a general purpose microprocessor such as a personal computer, which can be configured in accordance with the invention. However, the method could also be practiced with a dedicated processor, a processor under control from ROM or other “firmware,” or an integrated digital signal processing (DSP) circuit. Such variations and alternate embodiments are contemplated, and can be made without departing from the spirit and scope of the invention as defined in the appended claims.

We claim:

1. A method of digitally and automatically adjusting the audio volume of digitized speech signal, the signal represented by multiple digital bytes of encoded audio data organized into frames, transmitted through a distributed network and received at a digital receiving device for reproduction, comprising the steps of:
estimating an average frame volume estimate (VE) for each frame of data;
calculating from a plurality of successive said frame volume estimates (VE) at least one moving average of the volume estimates;
comparing said at least one moving average with a known desired level that is associated with a psychoacoustically desirable audio volume;
calculating, independently of any compression applied to said digital frame of data during encoding, a digital gain factor based upon the results of said comparing step; and
adjusting a volume level of the audio data based upon said digital gain factor.

2. The method of claim 1, wherein said step of calculating at least one moving average comprises calculating at least two moving averages with different time constants.

3. The method of claim 2, wherein said at least two moving averages include a fast moving average and a slow moving average, and wherein said step of calculating includes comparing said volume estimate with said fast and slow moving averages.

4. The method of claim 3 wherein said step of adjusting a volume level includes responding to said fast moving average when the digitized speech signal is increasing in volume.

5. The method of claim 4 wherein said step of adjusting a volume level further includes responding to said slow moving average when the digitized speech signal is decreasing in volume.

6. The method of claim 4 wherein said slow moving average is averaged over a time period of at least 100 ms.

7. The method of claim 4 wherein said fast moving average is calculated by averaging over a time period of less than 17 milliseconds.

8. The method of claim 3 wherein said step of adjusting a volume level includes responding to said slow moving average when the digitized speech signal is decreasing in volume.

9. The method of claim 1 wherein said step of estimating a volume estimate comprises extracting a bit field from a data frame, wherein said frame is larger than said bit field and said bit field is encoded with a scaling factor for decompressing audio data represented in said frame.

10. The method of claim 9 wherein said step of adjusting a volume level comprises expanding said digitized speech signal by multiplication with said gain factor, and said gain factor is selected to produce gain in the range between −12 and +12 decibels.

11. A system for digitally and automatically adjusting the audio volume of a digitized speech signal reproduced by a digital receiving device, the signal represented by multiple digital bytes of encoded audio data organized into frames, transmitted through a distributed network and received at the digital receiving device for reproduction, comprising:
a first module which estimates audio volume of each frame of data to produce for each said frame a corresponding volume estimate;
a second module which calculates from a plurality of successive said volume estimates at least one moving average of said volume estimates;
a third module which compares said at least one moving average with a predetermined desired level that corresponds to a psychoacoustically desirable audio volume;
a fourth module which calculates, independently of any compression applied to said digital frame of data during encoding, a digital gain factor based upon the comparison performed by said third module; and
a fifth module which rescales said audio data based upon said digital gain factor to produce audio data which will reproduce at a psychoacoustically acceptable level.

12. The system of claim 11, wherein the digital receiving device comprises a programmable computer and at least one of said modules comprises a software module programmed for execution by the receiving device.

13. The system of claim 12, wherein said second module is configured to calculate, for a given set of frames, at least two moving averages with different time constants.

14. The system of claim 13, wherein said second module calculates at least two moving averages, including a fast moving average and a slow moving average, and wherein said third module compares said volume estimate with said fast and slow moving averages.

15. The system of claim 14, wherein said fourth module adjusts a volume level in response to said fast moving average when the digitized speech signal is increasing in volume.

16. The system of claim 15, wherein said fourth module further adjusts a volume level in response to said slow moving average when the digitized speech signal is decreasing in volume.

17. The system of claim 16 wherein said slow moving average is averaged over a time period of at least 100 ms.

18. The system of claim 16 wherein said fast moving average is calculated by averaging over a time period of less than 17 milliseconds.

19. The system of claim 15 wherein said fourth module further adjusts a volume level in response to said slow moving average when the digitized speech signal is decreasing in volume.

20. The system of claim 14 wherein said third module estimates a volume estimate from a bit field included within a data frame, wherein said frame is larger than said bit field and said bit field is encoded with a scaling factor for decompressing audio data represented in said frame.
